(19) United States
(12) Patent Application Publication
(10) Pub. No.: US 2012/0073639 A1
(43) Pub. Date: Mar. 29, 2012

(54) SOLAR CELL AND A PRODUCTION METHOD THEREFOR

(75) Inventors: Jea Gun Park, Gyeonggi-do (KR); Su Hwan Lee, Seoul (KR); Dal Ho Kim, Jeollanam-do (KR); Tae Hun Shim, Gyeonggi-do (KR)

(73) Assignee: IUCF-HYU, Seoul (KR)

(21) Appl. No.: 13/257,307

(22) PCT Filed: Mar. 18, 2010
(86) PCT No.: PCT/KR2010/001685

§ 371 Date: Dec. 10, 2011

(30) Foreign Application Priority Data
Mar. 18, 2009 (KR) 10-2009-0023048

(51) Int. Cl. H01L 31/0224; H01L 31/18

(52) U.S. Cl. 136/255; 438/72; 257/E31.124

(57) ABSTRACT

The present invention provides a solar cell and manufacturing method thereof. The solar cell according to the present invention comprises: first and second electrodes, at least one of which has light transmitting properties; two or more photoelectric conversion layers positioned between the first and second electrodes; and a transflective conductive layer positioned between the photoelectric conversion layers. Further, tunneling layers are also provided between the photoelectric conversion layers and the transflective conductive layer. The efficiency of the solar cell can be improved, as compared with the prior art, by providing tunneling layers and a transflective conductive layer in this way.

### CROSS-REFERENCE TO RELATED APPLICATION

This application claims priority to Korean Patent Application No. 10-2009-0023048 filed on Mar. 18, 2009 and all the benefits accruing therefrom under 35 U.S.C. §119, the contents of which are incorporated by reference in their entirety.

### BACKGROUND

The present disclosure relates to a solar cell and manufacturing method thereof, and more particularly, to an organic solar cell and manufacturing method thereof, where two or more photoelectric conversion layers are stacked.

While fossil fuels are used, environmental pollution such as those contributing to global warming becomes an issue. Uranium that replaces fossil fuels has limitations in terms of radioactive contamination and the need for a nuclear waste facility. The demand for alternative energy sources, such as solar cells which convert solar energy to electrical energy, is growing, and thus research is being conducted in this field.

In the related art, single crystalline or polycrystalline silicon solar cells have been widely used. However, there are limitations in that their manufacturing costs are high and they are difficult to apply to flexible boards. To solve these limitations, research has being conducted on organic solar cells in recent years. Organic solar cells can be manufactured by a simple process and at low cost. Moreover, when using organic solar cells, large areas can be coated, and thin layers can be formed at low temperature. Furthermore, solar cells can be manufactured using almost all kinds of substrates from glass to plastic, and can be manufactured with various cross-sectional shapes such as a curved or spherical shape as with plastic molds, and can be bent and folded to be portable. Accordingly, organic solar cells can be attached to clothes, bags, and portable electronic and electrical equipment and used. Polymer blend thin films have high transparency to light, and thus can generate power while attached to a glass window of a building or vehicle. Accordingly, polymer blend thin films may have broader applications than opaque silicon solar cells.

However, despite these advantages, organic solar cells have a low power conversion efficiency and short life, and thus are not suitable for practical applications. That is, the efficiency of organic solar cells has been about 1% up to the late 1990s, and after 2000, their performance has been significantly enhanced due to the development of the morphology of polymer blend structures. For example, in 2003, an efficiency of about 3.5% was accomplished using P3HT (poly(3-hexylthiophene) and PCBM ([6,6]-phenyl-C61 butyric acid methyl ester) blend thin films, and using a thin LiF layer in a contact interface with an Al electrode [F. Padinger, R. S. Rittberger, N. S. Sariciftci, Adv. Func. Mater., 13, 85 (2003)].

However, polymer solar cells still have efficiency less than other thin film solar cells and require further improvement.

### SUMMARY

The present disclosure provides a solar cell and manufacturing method thereof, which lead to the enhancement of efficiency.

The present invention also provides a solar cell and manufacturing method thereof, in which first and second photoelectric conversion layers are stacked, and a tunneling layer and transflective conductive layer are formed between the first and second photoelectric conversion layers, leading to the enhancement of efficiency.

In accordance with an exemplary embodiment, a solar cell includes: first and second electrodes, at least one of the first and second electrodes having light transmittance; two or more photoelectric conversion layers positioned between the first and second electrodes; and a transflective conductive layer positioned between the photoelectric conversion layers.

Each of the photoelectric conversion layers may include a donor material and an acceptor material.

The photoelectric conversion layers may further include a blocking layer.

The solar cell may further include a tunneling layer positioned between the transflective conductive layer and photoelectric conversion layer.

The tunneling layer may include a metal oxide.

The tunneling layer may be a natural oxide layer.

The metal oxide may include Al₂O₃.

The solar cell may further include an electron injection layer positioned between the tunneling layer and photoelectric conversion layers.

The transflective conductive layer may have short-wavelength reflectivity and long-wavelength reflectivity which differ, in a visible light region.

The transflective conductive layer may include Au, Cu, or alloy thereof.

In accordance with another exemplary embodiment, a method of manufacturing a solar cell includes: forming a first electrode layer on a substrate; forming two or more photoelectric conversion layers on the first electrode layer, and tunneling layer and transflective conductive layer between the photoelectric conversion layers; and forming a second electrode layer on the photoelectric conversion layer.

The method may further include annealing each of the photoelectric conversion layers after each of the photoelectric conversion layers is formed.

The method may further include annealing all of the photoelectric conversion layers after all of the photoelectric conversion layers are formed.

The tunneling layer may be formed by depositing and oxidizing a metal material.

### BRIEF DESCRIPTION OF THE DRAWINGS

Exemplary embodiments can be understood in more detail from the following description taken in conjunction with the accompanying drawings, in which:

FIG. 1 is a sectional view illustrating a solar cell according to an embodiment of the present invention;

FIG. 2 is a graph showing reflectivities of metal materials used in the present invention;

FIG. 3 is a sectional view illustrating a solar cell according to another embodiment of the present invention;

FIG. 4 is a flowchart showing a method of a solar cell according to an embodiment of the present invention;

FIGS. 5 to 9 are sectional views showing processes in the order to illustrate a method of a solar cell according to an embodiment of the present invention;

FIG. 10 is a characteristic graph of a solar cell according to an embodiment of the present invention; and

FIGS. 11 to 14 are characteristic graphs of solar cells according to the comparison examples.

### DETAILED DESCRIPTION OF EMBODIMENTS

Hereinafter, embodiments of the present invention will be described in detail with reference to the drawing. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. In the figures, the dimensions of layers and regions may be exaggerated for clarity of illustration, and like reference numerals refer to like elements throughout. In the specification, it will be understood that when a layer (or film), a region, or a plate is referred to as being ‘on’ another layer, region, or plate, it can be directly on the other layer, region, or plate, or intervening layers, regions, or plates may also be present.

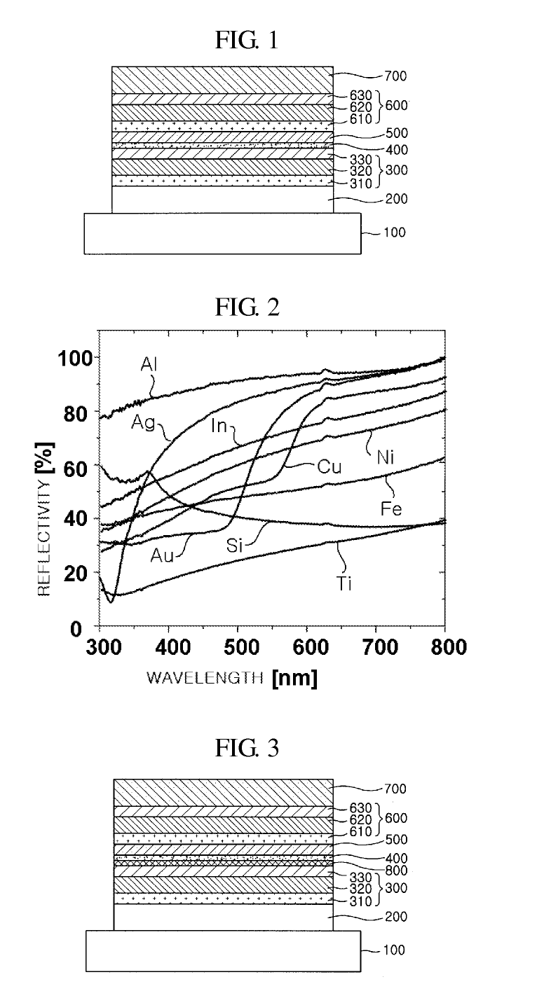

FIG. 1 is a sectional view of a solar cell according to an embodiment of the present invention. FIG. 2 is a graph showing reflectivities of metal materials which may be used in the present invention.

Referring to FIG. 1, a solar cell according to an embodiment of the present invention includes a first electrode layer 200, first photoelectric conversion layer 300, tunneling layer 400, transflective conductive layer 500, second photoelectric conversion layer 600, and second electrode layer 700. Also, the first photoelectric conversion layer 300 may include a first donor/acceptor layer 320 or a first hole transport layer 310, first donor/acceptor layer 320, and first blocking layer 330. The second photoelectric conversion layer 600 may include a second donor/acceptor layer 620 or a second hole transport layer 610, second donor/acceptor layer 620, and second blocking layer 630. In the embodiment of the present invention, the case where first/second photoelectric conversion layers 300 and 600 include first/second hole transport layers 310 and 610, first/second donor/acceptor layers 320 and 620, and first/second blocking layer 330 and 630, respectively, will be described. The solar cell according to an embodiment of the present invention has a structure in which first and second photoelectric conversion layer 300 and 600 with the same structure are stacked, and a tunneling layer 400 and transflective conductive layer 500 are formed therebetween. This enables light that is not absorbed in the first photoelectric conversion layer 300 to be absorbed in the second photoelectric conversion layer 600, thereby enhancing the efficiency.

A substrate 100 uses a transparent material with the light transmittance ratio of at least 110% or more, preferably, 80% or more in the wavelength of visible light. That is, the substrate 100 may use a transparent inorganic material such as quartz or glass, or a transparent plastic material such as polyethylene terephthalate (PET), polyethylene naphthalate (PEN), polycarbonate (PC), polystyrene (PS), polypropylene (PP), polyimide (PI), polyethylenesulfonate (PES), polyoxymethylene (POM), acrylonitrile-styrene (AS) resin, acrylonitrile-butadiene-styrene (ABS) resin, and triacetyl cellulose (TAC).

The first electrode layer 200 may be used as an anode, and use a conductive material with a high work function of about 4.5 eV or more and low resistance. The first electrode layer 200 uses a material with a high transparency because the first electrode layer 200 is a path through which light passing the substrate 100 reaches the first photoelectric conversion layer 300. Accordingly, the first electrode layer 200 may use a transparent conductive material such as indium tin oxide (ITO), zinc oxide (ZnO), indium-doped ZnO (IZO), gallium-doped ZnO (GZO), and aluminum-doped ZnO (AZO). The first electrode layer 200 may be formed using the thermal evaporation, electron-beam evaporation, RF or magnetron sputtering, or chemical deposition.

The first photoelectric conversion layer 300 includes the first hole transport layer 310, first donor/acceptor layer 320, and first blocking layer 330. The donor/acceptor layer 320 absorbs light to generate excitons. The hole transport layer 310 delivers holes separated from the excitons to the first electrode layer 200. The blocking layer 330 prevents the holes which has been separated from the excitons and excitons form which holes are not separated, from moving to the tunneling layer 400 and enables electrons to move to the tunneling layer 400.

The first hole transport layer 310 is formed of a conductive polymer material. For example, a conductive polymer such as poly(3,4-ethylene dioxythiopene) (PEDOT), poly(styrene sulphonate) (PSS), polyaniline, phtalocyanine, pentacene, poly(diphenylacetylene), poly(t-butyl)diphenylacetylene, poly(trifluoromethyl)diphenylacetylene, CuPc (Copper Phthalocyanine), poly(bistrifluoromethyl)acetylene, polybis(T-butildiphenyl)acetylene, poly(trimethylsilyl)diphenylacetylene, poly(carbazole)diphenylacetylene, polydiacetylene, polyphenylacetylene, polypyridineacetylene, polymethoxyphenylacetylene, polymethylphenylacetylene, poly(t-butil)phenylacetylene, polynitrophenylacetylene, poly(trifluoromethyl)phenylacetylene, poly(trimethylsilyl)phenylacetylene and derivatives thereof may be used in one or more mixtures. A mixture of PEDOT and PSS may be used. The conductive polymer materials may be formed using a common coating method, for example, spraying, spin coating, dipping, printing, doctor blading, or sputtering.

The first donor/acceptor layer 320 may be formed by blending donor and acceptor materials. A conductive polymer material including a π-electron may be used as the donor materials. For example, one of conductive polymers such as poly(3-hexylthiophene), polysiloxane carbazole, polyaniline, polyethylene oxide, poly(1-methoxy-4-(0-disperse red1)-2,5-phenylene-vinylene), polyindole, polycarbazole, polypyridazine, polyisothianaphthene, polyphenylene sulfide, polyvinylpyridine, polythiophene, polyfluorene, polypyridine and their derivatives or a mixture thereof may be used. The first donor/acceptor layer 320 uses a mixture of P3HT as the donor material and PCBM ([6,6]-phenyl-C61 butyric acid methyl ester) being a derivative of fullerene as the acceptor material. Herein, P3HT and PCBM may be mixed at a weight ratio (wt %) of 1:0.1 to 1:2.-20 wt % or 1 to 20 wt % The first donor/acceptor layer 320 also may be formed using a common coating method, for example, spraying, spin coating, dipping, printing, doctor blading, or sputtering.

The first blocking layer 330 is formed of a material having a great Highest Occupied Molecular Orbital (HOMO) level so as to prevent movement of the holes which has been separated from the excitons and excitons form which holes are not separated and allow movement of electrons. For example, the first blocking layer 330 is formed using bathocuproine (BCP). The first blocking layer 330 may be formed in the evaporation.

The tunneling layer 400 enables an electron delivered through the first blocking layer 330 to smoothly move to the transflective conductive layer 500. The tunneling layer 400 may be formed using a metal oxide. For example, Al₂O₃ may be used. The tunneling layer 400 may be formed depositing a metal material at low speed such that the metal material is naturally oxidized during the deposition. In addition, the tunneling layer 400 may be formed in various methods such as an oxidation using oxygen plasma.

The transflective conductive layer 500 delivers electrons that are delivered from the first photoelectric conversion layer 300 through the tunneling layer 400, to the second photoelectric conversion layer 600. That is, the transflective conductive layer 500 may be formed of at least a transflective conductive material such that light can be transmitted to the second photoelectric conversion layer 600. The transflective conductive layer 500 may be formed using at least one of Ag, Au, Mg, Ca, Li, Cu, and alloy thereof. For example, a material where the reflectivity in the short wavelength of 300-400 nm is different from the reflectivity in the long wavelength of 700-800 nm in the visible light region may be used. That is, as shown in a graph showing metal materials and their reflectivities of FIG. 2, Au, Cu, or alloy thereof may be used where the reflectivity in the short wavelength is different from the reflectivity in the long wavelength. For example, when the transflective conductive layer 500 is formed of Au, the reflectivity is low in a short wavelength region and high in a long wavelength region. Accordingly, in the light incident through the substrate 100, first electrode 200, and first photoelectric conversion layer 300, the light in a long wavelength region may be reflected by the transflective conductive layer 500, but the light in a short wavelength region may be incident to the second photoelectric conversion layer. A transparent conductive material such as ITO, ZnO, IZO, GZO, and AZO may be used instead of the transflective conductive layer 500. The material of the transflective conductive layer 500 is not limited to the above, but may be any material which has at least transflective characteristic, using an alloying or co-deposition.

The second photoelectric conversion layer 600 includes a second hole transport layer 610, second donor/acceptor layer 620, and second blocking layer 630, which are stacked on the transflective conductive layer 500. The second donor/acceptor layer 620 absorbs light which is lost in the first photoelectric conversion layer 300 to generate excitons. The second hole transport layer 610 delivers holes separated from the excitons of the second donor/acceptor layer 620, to the transflective conductive layer 500. The first blocking layer 630 prevents the holes which have been separated from the excitons and excitons from which holes are not separated, from moving to the second electrode layer 700 and enables electrons to move to the second electrode layer 700. That is, in the light incident through the first electrode 200, the light reflected by the transflective conductive layer 500 is absorbed in the first photoelectric conversion layer 300, but the light passing the transflective conductive layer 500 is absorbed in the second photoelectric conversion layer 600 to generate electrons and holes. In this case, the second photoelectric conversion layer 600 is formed in the same structure as the first photoelectric conversion layer 300. However, the second photoelectric conversion layer 600 and first photoelectric conversion layer 300 may be formed of different materials. For example, a donor material of the first photoelectric conversion layer 300 may be different from that of the second photoelectric conversion layer 600 in the band-gap energy. That is, donor materials of the first and second photoelectric conversion layer 300 and 600 each have a light absorption spectrum and one more peak wavelengths. Herein, at least one of the peak wavelengths may be different from that of the other donor material. For example, when the transflective conductive layer 500 is formed of Au, in the light incident through a first photoelectric conversion layer 300, the light in a long wavelength region is reflected by the transflective conductive layer 500. Thus, the first photoelectric conversion layer 300 may be formed to include a donor material having a peak wavelength in the red region. Since the light in a short wavelength region is incident to the second photoelectric conversion layer 600 through the transflective conductive layer 500, the second photoelectric conversion layer 600 may be formed to include a donor material having a peak wavelength in the blue or green region.

The second electrode layer 700 is used as a cathode and formed of a material having a work function less than the first electrode layer 200. For example, the second electrode layer 700 may be formed of a metal such as Mg, Al, or Ag or alloy thereof. Preferably, the second electrode layer 700 may be formed of Al with a high reflectivity.

FIG. 3 is a sectional view illustrating a solar cell according to another embodiment of the present invention.

Referring to FIG. 3, a solar cell according to another embodiment of the present invention includes a first electrode layer 200, first photoelectric conversion layer 300, electron injection layer 800, tunneling layer 400, transflective conductive layer 500, second photoelectric conversion layer 600, and second electrode layer 700. Also, the first photoelectric conversion layer 300 includes a first hole transport layer 310, first donor/acceptor layer 320, and first blocking layer 330. The photoelectric conversion layer 600 includes a second hole transport layer 610, second donor/acceptor layer 620, and second blocking layer 630.

That is, the solar cell according to another embodiment of the present invention has a structure where the electron injection layer 800 is added to the structure of FIG. 1.

The electron injection layer 800 injects electrons separated from the first photoelectric conversion layer 300 into the tunneling layer 400, thereby enhancing the interface property. The electron injection layer 800 may be formed of a material such as LiF and Liq. Also, the electron injection layer may be further formed between the second blocking layer 630 and second electrode 700.

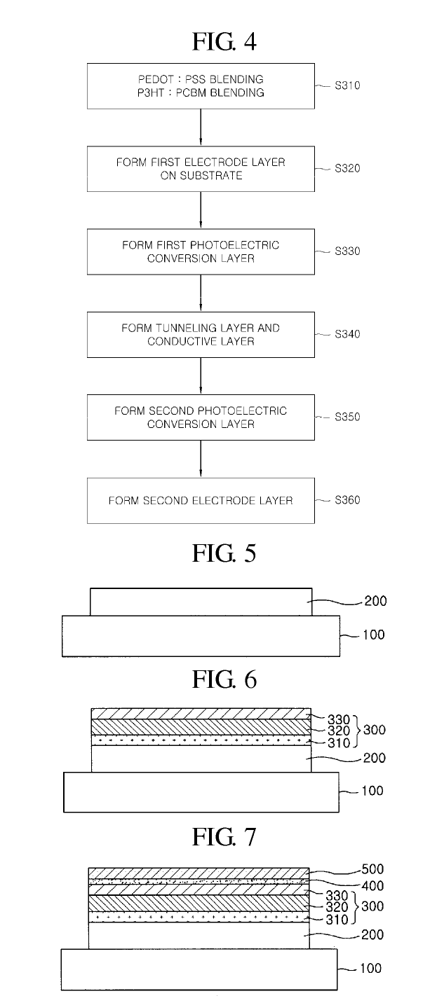

A method of manufacturing the solar cells according to embodiments of the present invention will be described with reference to FIGS. 4 to 9 as follows. FIG. 4 is a flow chart showing a method of manufacturing a solar cell according to an embodiment of the present invention. FIGS. 5 to 9 are sectional views illustrating a method of manufacturing a solar cell according to an embodiment of the present invention.

Referring to FIG. 4, materials forming a hole transport layer and donor/acceptor layer are generated (S310).

To generate the material forming a hole transport layer, a mixture of PEDOT and PSS is melted in an organic solvent such as isopropyl alcohol (IPA) and dispersed for at least 24 hours. The material forming a hole transport layer may be generated by mixing PEDOT and PSS with organic solvents, respectively, and then mixing the organic solvents. Also, the material forming a hole transport layer may be generated by mixing PEDOT and PSS. That is, the material forming a hole transport layer may be generated by mixing PEDOT and PSS without an organic solvent. To generate a material forming a donor/acceptor layer, P3HT and PCBM are mixed at a weight ratio (wt %) of 1:0.1 to 2:1. The mixture is melted in an organic solvent and dispersed for at least 72 hours. To remove macro particles make a problem in coating, the mixture is filtered with, for example, a 5 μm filter. Herein, chlorobenzene, benzene, chloroform, and THF may be used as an organic solvent. Also, a mixture thereof may be used. The material forming a donor/acceptor layer may be generated by mixing PEDOT and PSS with organic solvents, respectively, and then mixing the organic solvents.

Referring to FIGS. 4 and 5, the first electrode layer 200 is formed on the substrate 100 (S320). Herein, the substrate 100 is formed of a transparent material such as a glass. The first electrode layer 200 is formed of a transparent conductive material. The first electrode layer 200 may be formed to a thickness of approximately 100 to 200 nm. Subsequently, the substrate 100 with the first electrode layer 200 may be cleaned, and then processed by a UV and ozone. In this case, the cleaning process may be performed using an organic solvent, such as isopropyl alcohol and acetone, or pure water for approximately 10 minutes. The cleaned substrate 200 is dried, for example, at approximately 100° C. for one hour or more.

Referring to FIGS. 4 and 6, a first hole transport layer 310, first donor/acceptor layer 320, and first blocking layer 330 are sequentially formed on at least a portion of the first electrode layer 200 to form the first photoelectric layer 300 (S330). The first hole transport layer 310 and first donor/acceptor layer 320 may also be formed using a common coating method, for example, spraying, spin-coating, dipping, printing, doctor-blading, or sputtering. For example, the first hole transport layer 310 is formed by spin-coating the material forming a hole transport layer in which PEDOT and PSS are melted in an organic solvent, for example, at 2000 rpm for approximately 60 seconds and annealing the material in a nitrogen atmosphere at approximately 140° C. for 10 minutes. The first hole transport layer 320 is formed by spin-coating the material forming a hole transport layer in which PEDOT and PSS are melted in an organic solvent, for example, at 1000 rpm for approximately 60 seconds and annealing the material in a nitrogen atmosphere at approximately 125° C. for 10 minutes. Also, the first blocking layer 330 is formed by depositing BCP on the first donor/acceptor layer 320 in the evaporation. The first hole transport layer 310, first donor/acceptor layer 320, and first blocking layer 330 may be formed to a thickness of approximately 5 to 50 nm, approximately 10 to 150 nm, and approximately 5 to 30 nm.

Referring to FIGS. 4 and 7, the tunneling layer 400 and transflective conductive layer 500 are formed on the first blocking layer 330 (S340). The tunneling layer 400 may be formed of a metal oxide. The metal oxide may be formed by naturally oxidizing a metal material when deposited in the evaporation. For example, if a metal material is deposited in the evaporation with a pressure in a chamber being 10⁻⁶ to 10⁻⁷ Pa and a deposition rate being 0.1 to 1 Å/s, the metal material is deposited and naturally oxidized. As a result, a metal oxide is formed. Accordingly, the tunneling layer 400 may be formed of the metal oxide. Also, the tunneling layer 400 may be formed by depositing and oxidizing the metal material or by depositing the metal oxide. The tunneling layer 400 may be formed to a thickness facilitating the tunneling of electrons. For example, the tunneling layer 400 is formed in a thickness of appropriately 0.1 to 10 nm. The transflective conductive layer 500 is formed on the tunneling layer 400 in the evaporation. The transflective conductive layer 500 is formed by evaporating a metal material at a deposition rate greater than the metal material forming the tunneling layer 400, for example at approximately 0.5 to 7 Å/s. The transflective conductive layer 500 may be formed of a material which has short and long wavelength reflectivities different from each other in a visible light region. For example, Au, Cu, or alloy thereof may be used. For example, the transflective conductive layer 500 is formed to a thickness of approximately 5 to 20 nm.

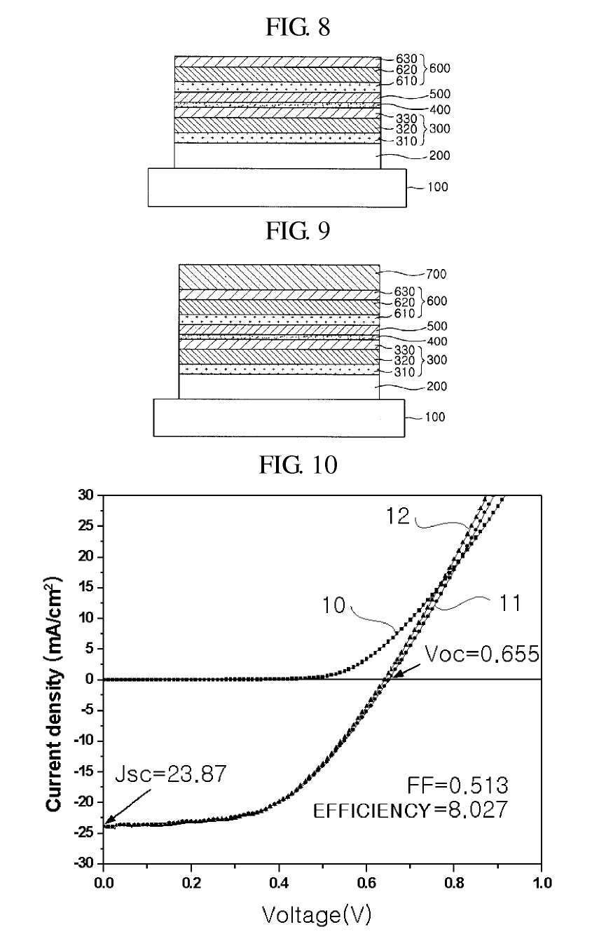

Referring to FIGS. 4 and 8, the second hole transport layer 610, second donor/acceptor layer 620, and second blocking layer 630 are sequentially formed on the transflective conductive layer 500 to form the second photoelectric conversion layer 600 (S350). The second hole transport layer 610 and second donor/acceptor layer 620 also may be formed using a common coating method, for example, spraying, spin-coating, dipping, printing, doctor-blading, or sputtering. For example, the second hole transport layer 610 and second donor/acceptor layer 620 may be formed in the same method as the first hole transport layer 310 and first donor/acceptor layer 32, respectively. That is, the second hole transport layer 610 is formed by spin-coating the material forming a hole transport layer in which PEDOT and PSS are melted in an organic solvent, for example, at 2000 rpm for approximately 60 seconds and annealing the material in a nitrogen atmosphere at approximately 140° C. for 10 minutes.

The second hole transport layer 620 is formed by spin-coating the material forming a hole transport layer in which PEDOT and PSS are melted in an organic solvent, for example, at 1000 rpm for approximately 60 seconds and annealing the material in a nitrogen atmosphere at approximately 125° C. for 10 minutes. For example, the second hole transport layer 610 and second donor/acceptor layer 620 may be formed of materials different from the first hole transport layer 310 and first donor/acceptor layer 320, respectively. In particular, the second donor/acceptor layer 620 may be formed of another material which absorbs light with a wavelength different from the first donor/acceptor layer 320. For example, the second donor/acceptor layer 620 may be formed of a material which absorbs light with a wavelength longer than the first donor/acceptor layer 320. The second blocking layer 630 is formed by depositing BCP on the second donor/acceptor layer 620 in the evaporation. The second hole transport layer 610, second donor/acceptor layer 620, and second blocking layer 630 may be formed to a thickness of approximately 5 to 50 nm, approximately 10 to 150 nm, and approximately 5 to 30 nm.

Referring to FIGS. 4 and 9, the second electrode layer 700 is formed on the second blocking layer 630 (S360). The second electrode layer 700 is formed by depositing a metal material in the evaporation. For example, the second electrode layer 700 may be formed at a deposition rate of approximately 0.5 to 7 Å/s in a chamber where a pressure is kept approximately from 10⁻⁶ to 10⁻³ Pa. The second electrode layer 700 may be formed of a metal such as Mg, Al, or Ag or alloy thereof. For example, the second electrode layer 700 may be formed of Al and to a thickness of approximately 50 to 100 nm.

It has been described above that annealing process is performed after the first hole transport layer 310, first donor/acceptor layer 320, second hole transport layer 610, and second donor/acceptor layer 620 are each formed. However, the annealing process may be performed not after the first hole transport layer 310 and first donor/acceptor layer 320 are formed, but only after the second hole transport layer 610 and second donor/acceptor layer 620 are formed.

In a solar cell according to an embodiment of the present invention with reference to FIG. 3, namely, when the electron injection layer 800 is formed between the first blocking layer 330 and tunneling layer 400, the electron injection layer 800 may be formed by depositing LiF and Liq in the evaporation. Also, even when the electron injection layer is further formed between the second blocking layer 630 and second electrode layer 700, the electron injection layer may be formed by depositing LiF and Liq in the evaporation. In this case, the electron injection layer 800 may be formed to a thickness of 0.1 to 10 nm. Hereinafter, the solar cell according to the present invention will be compared with solar cells according to related art comparison examples.

### Experiment Example

A solar cell is manufactured by stacking a 100 nm first electrode layer of ITO, 10 nm first hole transport layer of PEDOT:PSS, 70 nm first donor/acceptor layer of P3HT:PCBM, 12 nm first blocking layer of BCP, 0.5 nm electron injection layer of LiF, 0.5 nm tunneling layer of Al₂O₃, 10 nm transflective conductive layer of Au, 10 nm second hole transport layer of PEDOT:PSS, 70 nm second donor/acceptor layer of P3HT:PCBM, 12 nm second blocking layer of BCP, and 80 nm second electrode layer of Al on a glass substrate.

The properties of a solar cell are evaluated using an open circuit voltage (Voc), short circuit current (Jsc), fill factor (FF), and efficiency. The open circuit voltage (Voc) is a voltage which is generated when light is emitted without an external electrical load, namely a voltage when a current is zero. The short circuit current (Jsc) is a current which is generated when light is emitted with a short electrical contact, namely a current when a voltage is not applied. The fill factor (FF) is defined as a value that is obtained by dividing the multiplication of a changed current and voltage by the multiplication of the open circuit voltage Voc and short circuit current Jsc. The fill factor (FF) is always less than one because the open circuit voltage (Voc) and short circuit current (Jsc) are not simultaneously obtained. However, the efficiency of a solar cell becomes higher as the fill factor (FF) gets closer to 1. A resistance becomes greater as the fill factor (FF) gets lower. The efficiency is defined as a valued which is obtained by diving the multiplication of the open circuit voltage (Voc), short circuit current (Jsc), and fill factor (FF) by the strength of emitted light, namely as [Equation 1].

Efficiency=Vos×Jsc×FF/the strength of emitted light [Equation 1]

FIG. 10 is a characteristic graph of a solar cell according to an embodiment of the present invention, which shows a dark current and photo current. In the drawing, the reference numeral 10 indicates a dark current. The reference numerals 11 and 12 indicate photo currents of two solar cells formed in the same structure. In a case of the solar cell according to an embodiment of the present invention, the open circuit voltage (Voc) and short circuit current (Jsc) are measured as 0.655V and 23.87 mA/cm², respectively. Also, the fill factor (FF) is measured as 0.513. Accordingly, the efficiency is calculated as approximately 8.027.

### Comparison Example 1

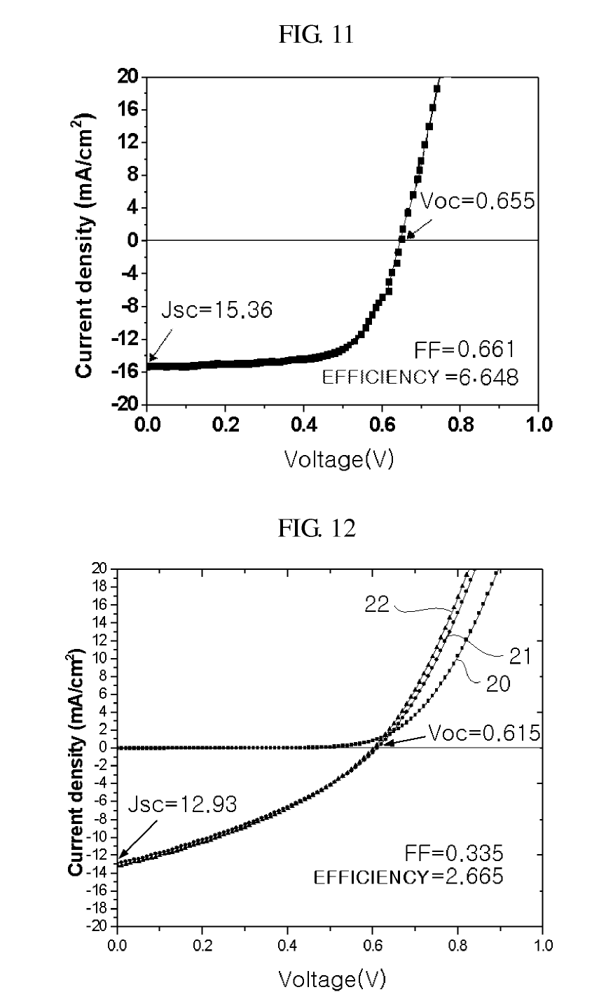

A solar cell is manufactured by stacking a 100 nm first electrode layer of ITO, 10 nm hole transport layer of PEDOT:PSS, 70 nm donor/acceptor layer of P3HT:PCBM, 12 nm blocking layer of BCP, 0.5 nm electron injection layer of LiF, and 80 nm second electrode layer of Al on a glass substrate. That is, the solar cell according to the comparison example 1 is manufactured by forming a photoelectric conversion layer in a single layer, unlike the present invention. FIG. 11 is a graph of features of a solar cell according to an embodiment of the comparison example 1. As shown in FIG. 11, for the solar cell according to the comparison example 1, the open circuit voltage (Voc), short circuit current (Jsc), and fill factor (FF) are measured as 0.655V, 15.36 mA/cm², and 0.661, respectively. Accordingly, the efficiency is calculated as approximately 6.648. That is, the present invention has the efficiency higher than the comparison example.

### Comparison Example 2

A solar cell is manufactured by stacking a 100 nm first electrode layer of ITO, 10 nm first hole transport layer of PEDOT:PSS, 70 nm first donor/acceptor layer of P3HT:PCBM, 12 nm first blocking layer of BCP, 10 nm second hole transport layer of PEDOT:PSS, 70 nm second donor/acceptor layer of P3HT:PCBM, 12 nm second blocking layer of BCP, and 80 nm second electrode layer of Al on a glass substrate. That is, the solar cell according to the comparison example 2 is manufactured by stacking two photoelectric conversion layers without forming an electron injection layer, tunneling layer, and transflective conductive layer, unlike the present invention. For the comparison example 2, the first blocking layer may be damaged when the second hole transport layer of PEDOT:PSS is spin-coated on the first blocking layer of BCP in a manufacturing process.

Also, FIG. 12 is a graph of features of a solar cell according to the comparison example. The reference numeral 20 indicates a dark current. The reference numerals 21 and 22 indicate photo currents of two solar cells formed in the same structure. For the solar cell according to the comparison example 2, the open circuit voltage (Voc), short circuit current (Jsc), and fill factor (FF) are measured as 0.615V, 12.93 mA/cm², and 0.335, respectively. Accordingly, the efficiency is calculated as approximately 2.665. That is, the present invention has the efficiency higher than the comparison example. It can be seen that a problem occurs in a process of the comparison example 2.

### Comparison Example 3

A solar cell is manufactured by stacking a 100 nm first electrode layer of ITO, 10 nm first hole transport layer of PEDOT:PSS, 70 nm first donor/acceptor layer of P3HT:PCBM, 12 nm first blocking layer of BCP, 3 nm transflective conductive layer of Al, 10 nm second hole transport layer of PEDOT:PSS, 70 nm second donor/acceptor layer of P3HT:PCBM, 12 nm second blocking layer of BCP, and 80 nm second electrode layer of Al on a glass substrate. That is, the solar cell according to the comparison example 3 is manufactured by using a transflective conductive layer of Al instead of Au without forming an electron injection layer and tunneling layer unlike embodiments of the present invention.

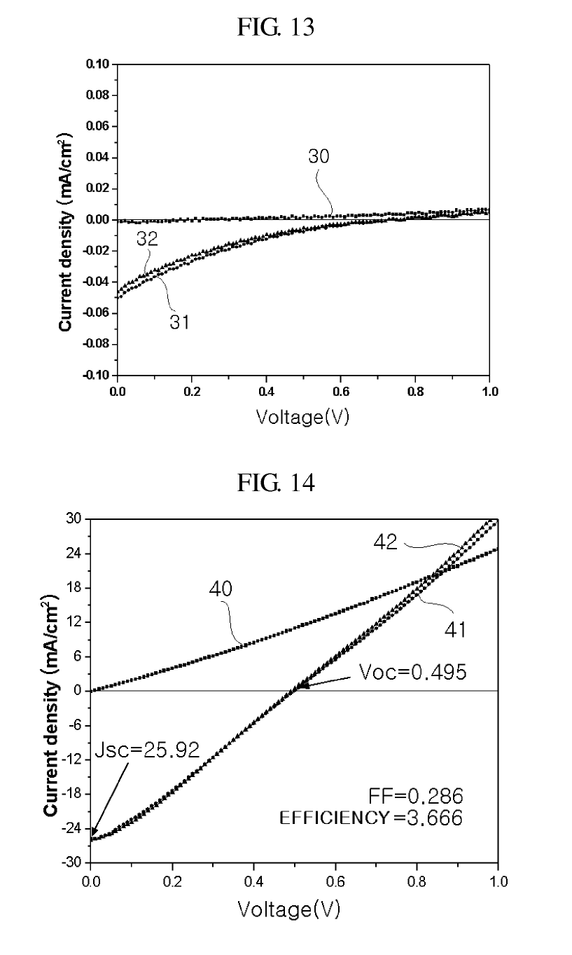

For the comparison example 3, the transflective conductive layer is formed of Al with a high reflectivity and to a thickness of 3 nm, considering the reflectivity of Al. However, the layer of Al is so thin that the resistance is significantly increased, thereby functioning as not a transflective layer but a resistance. That is, as shown in FIG. 13, since the open circuit voltage (Voc) and short circuit current is so small that the fill factor is difficult to calculate. Also, the efficiency is very poor at approximately 0.01%, and thus cannot be used as a solar cell.

### Comparison Example 4

A solar cell is manufactured by stacking an 100 nm thick first electrode layer of ITO, 10 nm first hole transport layer of PEDOT:PSS, 70 nm first donor/acceptor layer of P3HT:PCBM, 12 nm first blocking layer of BCP, 10 nm transflective conductive layer of Au, 10 nm second hole transport layer of PEDOT:PSS, 70 nm second donor/acceptor layer of P3HT:PCBM, 12 nm second blocking layer of BCP, and 80 nm second electrode layer of Al on a glass substrate. That is, a solar cell according to the comparison example 4 is manufactured without forming electron injection layer and tunneling layer, unlike the present invention.

FIG. 14 is a graph of features of a solar cell according to the comparison example 4. The reference numeral 40 indicates a dark current. The reference numerals 41 and 42 indicate photo currents of two solar cells formed in the same structure. For the solar cell according to the comparison example 4, the open circuit voltage (Voc), short circuit current (Jsc), and fill factor (FF) are measured as 0.495V, 25.92 mA/cm², and 0.286, respectively. Accordingly, the efficiency is calculated as approximately 3.666. That is, in the comparison example 4, the short circuit current (Jsc) somewhat increases compared to the present invention. However, due to a limitation in interface characteristic between a first blocking layer of BCP and transflective conductive layer of Au, the open circuit voltage Voc drops, and thus the fill factor (FF) and efficiency are lowered.

The results of the above experiment examples and comparison examples are as the following Table 1.

TABLE 1

| | | | | Efficiency |
|---|---|---|---|---|
| | Voc (V) | Jsc (mA/cm²) | FF | (%) |
| Experiment Example | 0.655 | 23.87 | 0.513 | 8.027 |
| Comparison Example 1 | 0.655 | 15.36 | 0.611 | 6.648 |
| Comparison Example 2 | 0.615 | 12.93 | 0.335 | 2.665 |
| Comparison Example 3 | 0.7 | 0.05 | — | 0.01 |
| Comparison Example 4 | 0.495 | 25.92 | 0.286 | 3.666 |

From the above-described, it can be seen that the solar cell according to an embodiment of the present invention has the open circuit voltage (Voc) and short circuit current (Jsc) higher than the solar cells. Accordingly, the fill factor (FF) is enhanced, and thus the efficiency can be significantly enhanced.

As described above, the technical idea of the present invention has been specifically described with respect to the above embodiments, but it should be noted that the foregoing embodiments are provided only for illustration while not limiting the present invention. Various embodiments may be provided to allow those skilled in the art to understand the scope of the preset invention.

The present invention provides the solar cell with first and second photoelectric conversion layers between first and second electrode layers, and tunneling layer and transflective conductive layer between the first and second photoelectric conversion layers. Also, an electric injection layer is further provided between the first photoelectric conversion layer and tunneling layer.

The tunneling layer and transflective conductive layer enable electrons to smoothly move and enable the second photoelectric conversion layer to absorb light which is not absorbed in the firs photoelectric conversion layer, thereby enhancing the efficiency of the solar cell.

Although a solar cell and manufacturing method thereof have been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A solar cell comprising:
first and second electrodes, at least one of the first and second electrodes having light transmittance;
two or more photoelectric conversion layers positioned between the first and second electrodes; and
a transflective conductive layer positioned between the photoelectric conversion layers.

2. The solar cell of claim 1, wherein each of the photoelectric conversion layers comprises a donor material and an acceptor material.

3. The solar cell of claim 2, wherein the photoelectric conversion layers further comprise a blocking layer.

4. The solar cell of claim 1, further comprising a tunneling layer positioned between the transflective conductive layer and photoelectric conversion layer.

5. The solar cell of claim 4, wherein the tunneling layer comprises a metal oxide.

6. The solar cell of claim 5, wherein the tunneling layer is a natural oxide layer.

7. The solar cell of claim 5, wherein the metal oxide comprises Al₂O₃.

8. The solar cell of claim 3, further comprising an electron injection layer positioned between the tunneling layer and photoelectric conversion layers.

9. The solar cell of claim 1, wherein the transflective conductive layer has short-wavelength reflectivity and long-wavelength reflectivity which differ, in a visible light region.

10. The solar cell of claim 9, wherein the transflective conductive layer comprises Au, Cu, or alloy thereof.

11. A method of manufacturing a solar cell, the method comprises:
forming a first electrode layer on a substrate;
forming two or more photoelectric conversion layers on the first electrode layer, and tunneling layer and transflective conductive layer between the photoelectric conversion layers; and
forming a second electrode layer on the photoelectric conversion layer.

12. The method of claim 11, further comprising annealing each of the photoelectric conversion layers after each of the photoelectric conversion layers is formed.

13. The method of claim 11, further comprising annealing all of the photoelectric conversion layers after all of the photoelectric conversion layers are formed.

14. The method of claim 11, wherein the tunneling layer is formed by depositing and oxidizing a metal material.
